(19) United States
(12) Patent Application Publication
(10) Pub. No.: US 2015/0102395 A1
(43) Pub. Date: Apr. 16, 2015

(54) SEMICONDUCTOR DEVICE INCLUDING DECOUPLING CAPACITOR AND METHOD OF FORMING THE SAME

(71) Applicants: Jae-Hwa Park, Yongin-si (KR); Kwang-Jin Moon, Hwaseong-si (KR); Byung-Lyul Park, Seoul (KR)

(72) Inventors: Jae-Hwa Park, Yongin-si (KR); Kwang-Jin Moon, Hwaseong-si (KR); Byung-Lyul Park, Seoul (KR)

(21) Appl. No.: 14/511,801

(22) Filed: Oct. 10, 2014

(30) Foreign Application Priority Data
Oct. 11, 2013 (KR) 10-2013-0121483

(51) Int. Cl. H01L 27/108; H01L 23/64; H01L 49/02; H01L 23/48; H01L 29/423; H01L 29/51

(52) U.S. Cl. CPC H01L 27/10829; H01L 27/10823; H01L 29/4236; H01L 29/51; H01L 28/40; H01L 23/481; H01L 23/64; H01L 2223/6666
USPC 257/301

(57) ABSTRACT

An integrated circuit device includes a semiconductor substrate having first and second semiconductor regions therein, a gate trench in the first semiconductor region and a gate electrode in the gate trench. The gate electrode has an upper surface below a surface of the semiconductor substrate. A semiconductor well region is provided in the second semiconductor region. A capacitor trench extends in the semiconductor well region and an upper capacitor electrode extends in the capacitor trench. An electrical interconnect (e.g., conductive plug) is provided, which is electrically connected to the upper capacitor electrode at an interface therebetween. This interface has an upper surface below the surface of the semiconductor substrate.

### CROSS-REFERENCE TO PRIORITY APPLICATION

This application claims priority under 35 U.S.C. §119 to Korean Patent Application No. 10-2013-0121483, filed Oct. 11, 2013, the disclosure of which is hereby incorporated herein by reference in its entirety.

### BACKGROUND

1. Field

Embodiments of the inventive concept relate to a semiconductor device including capacitors therein, and a method of forming the same.

2. Description of Related Art

In semiconductor devices, various technologies using decoupling capacitors are being studied in order to respond to irregular changes in data signals.

### SUMMARY

Embodiments of the inventive concept provide a semiconductor device including a decoupling capacitor configured to prevent irregular changes of signals and achieve high integration, and a method of forming the same.

The technical objectives of the inventive concept are not limited to the above disclosure; other objectives may become apparent to those of ordinary skill in the art based on the following descriptions.

In accordance with an aspect of the inventive concept, a semiconductor device is provided. The semiconductor device includes a semiconductor substrate having a cell region and a peripheral circuit region. A gate trench is formed in the cell region of the semiconductor substrate. A gate electrode is disposed in the gate trench. A gate dielectric layer is formed between the gate electrode and the semiconductor substrate. A well is formed in the peripheral circuit region of the semiconductor substrate. A capacitor trench is formed in the well and having the same shape as the gate trench. An upper electrode is formed in the capacitor trench. A capacitor dielectric layer is formed between the upper electrode and the well. A through-electrode electrically connected to the upper electrode is disposed. Upper ends of the gate electrode and the upper electrode are formed at a lower level than an upper end of the semiconductor substrate.

In some embodiments, a bottom of the capacitor trench may be formed at the same level as a bottom of the gate trench. In other embodiments, the upper electrode may have the same shape as the gate electrode. In still other embodiments, the upper end of the upper electrode may be formed at the same level as the upper end of the gate electrode. In still other embodiments, a lower end of the upper electrode may be formed at the same level as a lower end of the gate electrode. In still other embodiments, the capacitor dielectric layer may be the same material layer as the gate dielectric layer. In still other embodiments, the upper electrode may be the same material layer as the gate electrode. In still other embodiments, the semiconductor substrate may include p-type impurities, and the well includes n-type impurities. In still other embodiments, the well may be connected to a ground (GND).

In still other embodiments, the through-electrode may pass through the semiconductor substrate, and an upper end of the through-electrode may be formed at a higher level than the upper electrode. In still other embodiments, a lower end of the through-electrode may be formed at a lower level than the well. In still other embodiments, the semiconductor device may further include an insulating layer formed on the semiconductor substrate and covering the gate electrode and the upper electrode, a bit line formed in the insulating layer and connected to the cell region of the semiconductor substrate, and an interconnection formed in the insulating layer at the same level as the bit line, and connected to the upper electrode. In still other embodiments, the through-electrode may be electrically connected to the upper electrode via the interconnection. In still other embodiments, the semiconductor device may further include a buried contact plug passing through the insulating layer and in contact with the cell region of the semiconductor substrate, a cell lower electrode formed in the insulating layer and connected to the buried contact plug, a cell capacitor dielectric layer formed on the cell lower electrode, and a cell upper electrode formed on the cell capacitor dielectric layer.

In accordance with another aspect of the inventive concept, a semiconductor device is provided. The semiconductor device includes a first semiconductor chip disposed on a substrate. A second semiconductor chip is disposed on the first semiconductor chip. An encapsulant is formed on the substrate and covering the first and second semiconductor chips. The second semiconductor chip includes a semiconductor substrate including a cell region and a peripheral circuit region. A gate trench is formed in the cell region of the semiconductor substrate. A gate electrode is formed in the gate trench. A gate dielectric layer is formed between the gate electrode and the semiconductor substrate. A well is formed in the peripheral circuit region of the semiconductor substrate. A capacitor trench is formed in the well to have the same shape as the gate trench. An upper electrode is formed in the capacitor trench. A capacitor dielectric layer is formed between the upper electrode and the well. A first through-electrode electrically connected to the upper electrode is formed. Upper ends of the gate electrode and the upper electrode are formed at a lower level than an upper end of the semiconductor substrate.

In some embodiments, the semiconductor device may further include a second through-electrode formed in the first semiconductor chip. A first connection terminal may be formed between the second through-electrode and the substrate. A second connection terminal is formed between the first through-electrode of the second semiconductor chip and the second through-electrode of the first semiconductor chip. In other embodiments, the semiconductor device may further include an interposer formed between the first semiconductor chip and the second semiconductor chip, a third through-electrode formed in the interposer, and a third connection terminal formed between the third through-electrode and the second through-electrode of the first semiconductor chip. The second connection terminal may be disposed between the third through-electrode and the first through-electrode of the second semiconductor chip. In still other embodiments, the semiconductor device may further include a finger electrode formed in the interposer and in contact with the third through-electrode. The second connection terminal may be disposed between the finger electrode and the first through-electrode of the second semiconductor chip, and offset from the third connection terminal.

In still other embodiments, the semiconductor device may further include a third semiconductor chip disposed on the second semiconductor chip, and a fourth connection terminal formed between the third semiconductor chip and the first through-electrode. In accordance with still another aspect of the inventive concept, a semiconductor device is provided. The semiconductor device includes a first semiconductor chip formed on a substrate. A second semiconductor chip is disposed on the first semiconductor chip. An encapsulant is formed on the substrate and covering the first and second semiconductor chips.

The second semiconductor chip includes a semiconductor substrate including a cell region and a peripheral circuit region. A gate trench is formed in the cell region of the semiconductor substrate. A gate electrode is formed in the gate trench. A gate dielectric layer is formed between the gate electrode and the semiconductor substrate. A well is formed in the peripheral circuit region of the semiconductor substrate. A capacitor trench is formed in the well and having the same shape as the gate trench. An upper electrode is formed in the capacitor trench. A capacitor dielectric layer is formed between the upper electrode and the well. Upper ends of the gate electrode and the upper electrode are formed at a lower level than an upper end of the semiconductor substrate, and the upper electrode is electrically connected to the first semiconductor chip.

An integrated circuit device according to further embodiments of the invention includes a semiconductor substrate having first and second semiconductor regions therein. These semiconductor regions may be classified as a cellular array region and a peripheral circuit region, which may surround and/or be closely adjacent a cellular array region. A gate trench is provided in the first semiconductor region and a gate electrode is provided in the gate trench. The gate electrode can have an upper surface below a surface of the semiconductor substrate. A semiconductor well region is also provided in the second semiconductor region and a capacitor trench is provided in the semiconductor well region. An upper capacitor electrode is provided in the capacitor trench and an electrical interconnect (e.g., conductive plug) is provided, which is electrically connected to the upper capacitor electrode at an interface therebetween, the interface having an upper surface below the surface of the semiconductor substrate.

According to additional embodiments of the invention, a lowermost portion of the gate electrode in the gate trench and a lowermost portion of the upper capacitor electrode in the capacitor trench have equivalent cross-sections when viewed in a first direction parallel to the surface of the semiconductor substrate. In addition, a depth of the gate trench in the semiconductor substrate can be equivalent to a depth of the capacitor trench in the semiconductor substrate. According to still further embodiments of the invention, the gate electrode is separated from a sidewall and bottom of the gate trench by a gate dielectric layer, the upper capacitor electrode is separated from a sidewall and bottom of the capacitor trench by a capacitor dielectric layer and the gate dielectric layer and capacitor dielectric layer are equivalent materials. The upper capacitor electrode and the gate electrode may also be equivalent materials. According to additional embodiments of the invention, the semiconductor well region may form a P-N junction with a surrounding portion of the semiconductor substrate. This semiconductor well region can be electrically connected to a reference potential, such as a ground signal line (GND), to prevent the well region from electrically floating.

According to still further embodiments of the invention, the gate electrode can be a gate electrode of a DRAM access transistor, the upper capacitor electrode can be an upper capacitor electrode of a decoupling capacitor, and the gate electrode can be electrically connected to a word line, which extends parallel to the upper capacitor electrode of the decoupling capacitor. Moreover, the upper capacitor electrode of the decoupling capacitor can be electrically connected to a patterned interconnection line extending above the surface of the semiconductor substrate, and the first semiconductor region can have a bit line thereon at the same height as the patterned interconnection line relative to the surface of the semiconductor substrate.

According to yet further embodiments of the invention, a through-substrate via (TSV) may be provided, which extends through the semiconductor substrate, and a through-substrate electrode may be provided in the TSV, which can be electrically connected to the upper capacitor electrode of the decoupling capacitor via the patterned interconnection line and electrical interconnect. A solder bond may be provided, which is electrically connected to the upper capacitor electrode of the decoupling capacitor via the patterned interconnection line and electrical interconnect. According to further embodiments of the invention, a second semiconductor substrate may be provided, which has a second decoupling capacitor therein. A solder bond is provided, which electrically connects an electrode of the second decoupling capacitor to the TSV. In this manner, the integrated circuit device may be configured as a vertically integrated multi-chip DRAM device.

In accordance with still another aspect of the inventive concept, a method of forming a semiconductor device is provided. The method includes providing a semiconductor substrate including a cell region and a peripheral circuit region. A well is formed in the peripheral circuit region of the semiconductor substrate. A gate trench is formed in the cell region of the semiconductor substrate. A capacitor trench is in the well. The capacitor trench has the same shape as the gate trench. A gate dielectric layer is formed in the gate trench. A capacitor dielectric layer is formed in the capacitor trench. A gate electrode is formed on the gate dielectric layer. An upper electrode is formed on the capacitor dielectric layer. A through-electrode electrically connected to the upper electrode is formed. Upper ends of the gate electrode and the upper electrode are formed at a lower level than the semiconductor substrate. In some embodiments, the upper electrode may be the same material layer formed at the same time as the gate electrode. In other embodiments, the capacitor dielectric layer may be the same material layer formed at the same time as the gate dielectric layer. In still other embodiments, a bottom of the capacitor trench may be formed at the same level as a bottom of the gate trench. In still other embodiments, the upper end of the upper electrode may be formed at the same level as the upper end of the gate electrode.

Details of other embodiments are included in the detailed description and drawings.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference numerals denote the same respective parts throughout the different views. The drawings are not necessarily to scale, emphasis instead being placed upon illustrating the principles of the inventive concepts. In the drawings:

FIG. 1 is a cross-sectional view for describing a semiconductor device in accordance with embodiments of the inventive concept, and FIGS. 2 to 4 are enlarged views showing a part of FIG. 1 in detail;

FIGS. 5 to 10 are cross-sectional views for describing a semiconductor device in accordance with embodiments of the inventive concept;

FIG. 11 is a cross-sectional view for describing a semiconductor device in accordance with embodiments of the inventive concept, and FIG. 12 is an enlarged view showing a part of FIG. 11 in detail;

FIG. 13 is a cross-sectional view for describing a semiconductor device in accordance with embodiments of the inventive concept, and FIG. 14 is an enlarged view showing a part of FIG. 13 in detail;

FIG. 15 is a cross-sectional view for describing a semiconductor device in accordance with embodiments of the inventive concept, and FIG. 16 is an enlarged view showing a part of FIG. 15 in detail;

FIG. 17 is a cross-sectional view for describing a semiconductor device in accordance with embodiments of the inventive concept, and FIG. 18 is an enlarged view showing a part of FIG. 17 in detail;

FIGS. 19 to 26 are cross-sectional views for describing a method of forming a semiconductor device in accordance with embodiments of the inventive concept;

FIG. 27 is a layout for describing a semiconductor module in accordance with embodiments of the inventive concept;

FIG. 28 is a perspective view showing an electronic apparatus in accordance with embodiments of the inventive concept, and FIG. 29 is a system block diagram showing an electronic apparatus in accordance with embodiments of the inventive concept; and

FIGS. 30 to 32 are perspective views showing electronic apparatuses in accordance with embodiments of the inventive concept, and FIG. 33 is a system block diagram of the electronic apparatuses in accordance with embodiments of the inventive concept.

### DETAILED DESCRIPTION OF THE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concept to those skilled in the art.

The terminology used herein to describe embodiments of the invention is not intended to limit the scope of the invention. The articles “a,” “an,” and “the” are singular in that they have a single referent; however, the use of the singular form in the present document should not preclude the presence of more than one referent. In other words, elements of the invention referred to in the singular may number one or more, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

In the drawings, the sizes and relative sizes of layers and regions may be exaggerated for clarity. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. In the following explanation, the same reference numerals denote the same components throughout the specification.

Spatially relative terms, such as “beneath,” “below,” “lower,” “above,” “upper,” and the like may be used herein to describe the relationship of one element or feature to another, as illustrated in the drawings. It will be understood that such descriptions are intended to encompass different orientations in use or operation in addition to orientations depicted in the drawings. For example, if a device is turned over, elements described as “below” or “beneath” other elements or features would then be oriented “above” the other elements or features. Thus, the term “below” is intended to mean both above and below, depending upon overall device orientation.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted into non-implanted region.

Terms such as “front side” and “back side” may be used in a relative sense herein to facilitate easy understanding of the inventive concept. Accordingly, “front side” and “back side” may not refer to any specific direction, location, or component, and may be used interchangeably. For example, “front side” may be interpreted as “back side” and vice versa. Also, “front side” may be expressed as “first side,” and “back side” may be expressed as “second side,” and vice versa. However, “front side” and “back side” cannot be used interchangeably in the same embodiment.

The term “near” is intended to mean that one among two or more components is located within relatively close proximity of a certain other component. For example, it should be understood that when a first end is near a first side, the first end may be closer to the first side than a second end, or the first end may be closer to the first side than to a second side.

Unless otherwise defined, all terms (including technical and scientific terms) used herein are to be interpreted as is customary in the art to which this invention belongs. It will be further understood that terms in common usage should also be interpreted as is customary in the relevant art and not in an idealized or overly formal sense unless expressly so defined herein.

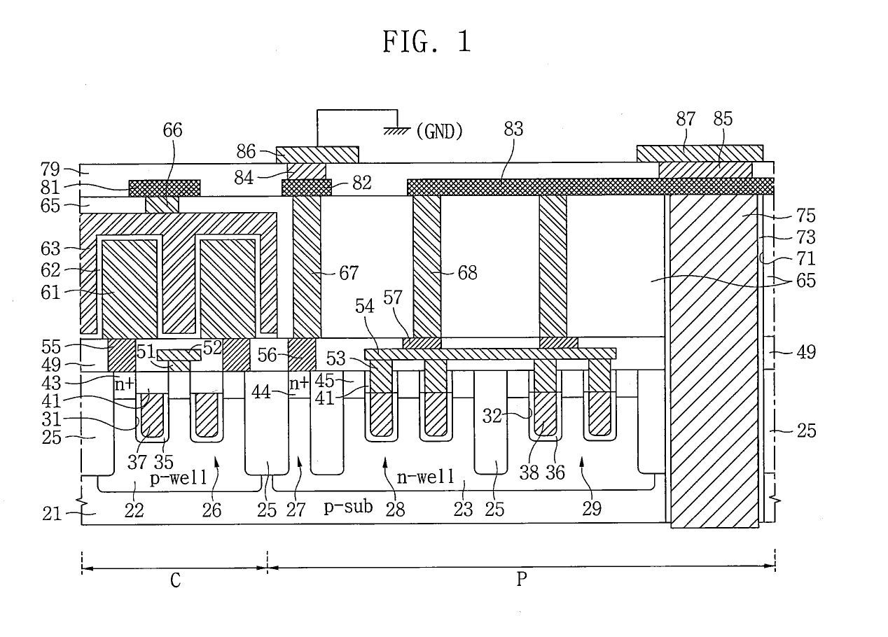

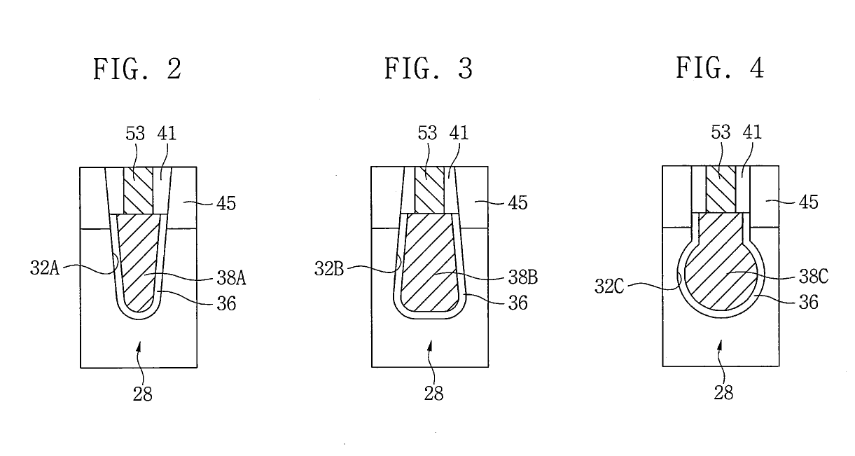

FIG. 1 is a cross-sectional view for describing a semiconductor device in accordance with embodiments of the inventive concept, and FIGS. 2 to 4 are enlarged views showing a part of FIG. 1 in detail. Referring to FIG. 1, a first well 22 and a second well 23 may be formed in a predetermined region of a semiconductor substrate 21 including a cell region C and a peripheral circuit region P. A device isolation layer 25 defining a first active region 26, a second active region 27, a third active region 28, and a fourth active region 29 may be formed on the semiconductor substrate 21. A gate trench 31 may be formed in the first active region 26. A capacitor trench 32 may be formed in the third active region 28 and the fourth active region 29.

A gate dielectric layer 35 covering a sidewall and a bottom of the gate trench 31 may be formed. A gate electrode 37 may be formed in the gate trench 31. A capacitor dielectric layer 36 covering a sidewall and a bottom of the capacitor trench 32 may be formed. An upper electrode 38 may be formed in the capacitor trench 32. The upper electrode 38, the capacitor dielectric layer 36, and the second well 23 may configure a decoupling capacitor. The second well 23 may be connected to a ground GND. The second well 23 may function as a lower electrode.

Capping patterns 41 may be formed on the gate electrode 37 and the upper electrode 38. Source/drain areas 43 may be formed on the first active region 26. A first impurity area 44 may be formed on the second active region 27. Second impurity areas 45 may be formed on the third active region 28 and the fourth active region 29.

A first insulating layer 49 covering the device isolation layer 25, the source/drain areas 43, the capping patterns 41, the first impurity area 44, and the second impurity areas 45 may be formed. A bit plug 51 and a bit line 52 may be formed in the first insulating layer 49. First plugs 53 passing through the first insulating layer 49 and the capping patterns 41 and in contact with the upper electrode 38 may be formed. A first interconnection 54 in contact with the first plugs 53 may be formed in the first insulating layer 49. A buried contact plug 55 passing through the first insulating layer 49 and in contact with one selected from the source/drain areas 43 may be formed. A second plug 56 passing through the first insulating layer 49 and in contact with the first impurity area 44 may be formed. A third plug 57 passing through the first insulating layer 49 and in contact with the first interconnection 54 may be formed.

A cell lower electrode 61 connected to the buried contact plug 55 may be formed on the first insulating layer 49. A cell capacitor dielectric layer 62 may be formed on the cell lower electrode 61. A cell upper electrode 63 may be formed on the cell capacitor dielectric layer 62. The cell lower electrode 61, the cell capacitor dielectric layer 62, and the cell upper electrode 63 may configure a cell capacitor. A second insulating layer 65 covering the cell upper electrode 63 and the first insulating layer 49 may be formed. A fourth plug 66, a fifth plug 67, and a sixth plug 68 passing through the second insulating layer 65 may be formed.

A via hole 71 passing through the second insulating layer 65, the first insulating layer 49, the device isolation layer 25, and the semiconductor substrate 21 may be formed. A via insulating layer 73 covering a sidewall of the via hole 71 may be formed. A through-electrode 75 filling the via hole 71 may be formed. A lower end of the through-electrode 75 may be exposed. A third insulating layer 79 may be formed on the second insulating layer 65. A second interconnection 81, a third interconnection 82, a fourth interconnection 83, a seventh plug 84, and an eighth plug 85 may be formed in the third insulating layer 79. A first pad 86 and a second pad 87 may be formed on the third insulating layer 79. The first pad 86 may be connected to the ground GND.

The second pad 87 may be a data input/output pad. The second pad 87 may be electrically connected to the bit line 52, the gate electrode 37, or the cell upper electrode 63. The upper electrode 38, the capacitor dielectric layer 36, and the second well 23 may configure a decoupling capacitor. The second pad 87 may be connected to the through-electrode 75 and the upper electrode 38. The decoupling capacitor 23, 36, and 38 may function to reduce/block noise of a data signal flowing through the second pad 87 or the through-electrode 75. Capacitance of the decoupling capacitors 23, 36, and 38 may significantly increase compared to that in the related art. The decoupling capacitor 23, 36, and 38 may be formed close to the second pad 87 and the through-electrode 75. A path between the upper electrode 38 and the second pad 87 may be minimized.

The capacitor trench 32 may have substantially the same size and shape as the gate trench 31. The capacitor trench 32 may have substantially the same horizontal width and vertical depth as the gate trench 31. The bottom of the capacitor trench 32 may be formed at substantially the same level as the bottom of the gate trench 31. The gate dielectric layer 35 and the capacitor dielectric layer 36 may have substantially the same thickness. The gate dielectric layer 35 and the capacitor dielectric layer 36 may include the same material layer. The gate electrode 37 and the upper electrode 38 may include the same material layer.

The upper electrode 38 may have substantially the same size and shape as the gate electrode 37. The upper electrode 38 may have substantially the same horizontal width as the gate electrode 37. Upper ends of the upper electrode 38 and the gate electrode 37 may be formed at lower levels than upper ends of the capacitor trench 32 and the gate trench 31. The upper ends of the upper electrode 38 and the gate electrode 37 may be formed at lower levels than upper ends of the first active region 26, the third active region 28, and the fourth active region 29. The upper end of the upper electrode 38 may be formed substantially at the same level as the upper end of the gate electrode 37. A lower end of the upper electrode 38 may be formed substantially at the same level as a lower end of the gate electrode 37.

Referring to FIG. 2, a capacitor trench 32A may have an upper width greater than a lower width. An upper electrode 38A may be formed in the capacitor trench 32A. A capacitor dielectric layer 36 may be formed in a third active region 28 and the upper electrode 38A. The upper electrode 38A may have an upper width greater than a lower width. A capping pattern 41 and a first plug 53 may be formed on the upper electrode 38A. The first plug 53 may be in contact with the upper electrode 38A through the capping pattern 41. The first plug 53 may have a different horizontal width from the upper electrode 38A. The horizontal width of the first plug 53 may be smaller than that of the upper electrode 38A.

Referring to FIG. 3, a capacitor trench 32B may have an upper width smaller than a lower width. An upper electrode 38B may be formed in the capacitor trench 32B. The upper electrode 38B may have an upper width smaller than a lower width.

Referring to FIG. 4, a capacitor trench 32C may have a spherical-shaped lower end having greater width than an upper end. An upper electrode 38C may be formed in the capacitor trench 32C. The upper electrode 38C may have a spherical-shaped lower end having a greater width than an upper end.

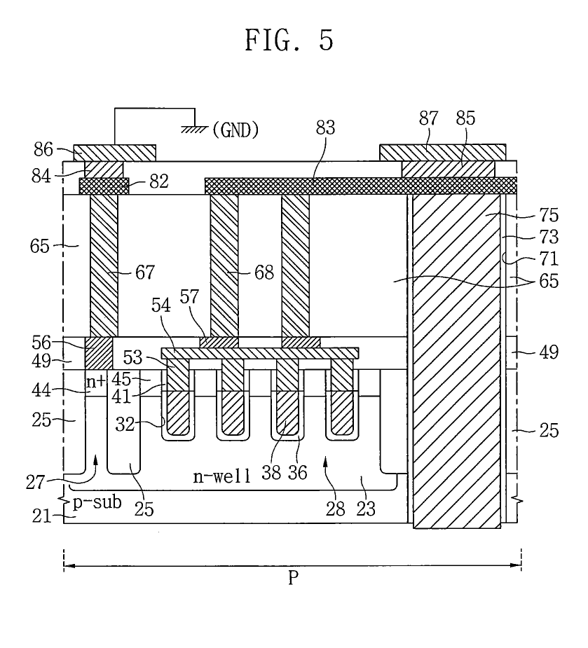

FIGS. 5 to 10 are cross-sectional views for describing semiconductor devices in accordance with embodiments of the inventive concept.

Referring to FIG. 5, a third active region 28 may have various horizontal widths. For example, four capacitor trenches 32 crossing the third active region 28 and parallel to each other may be formed.

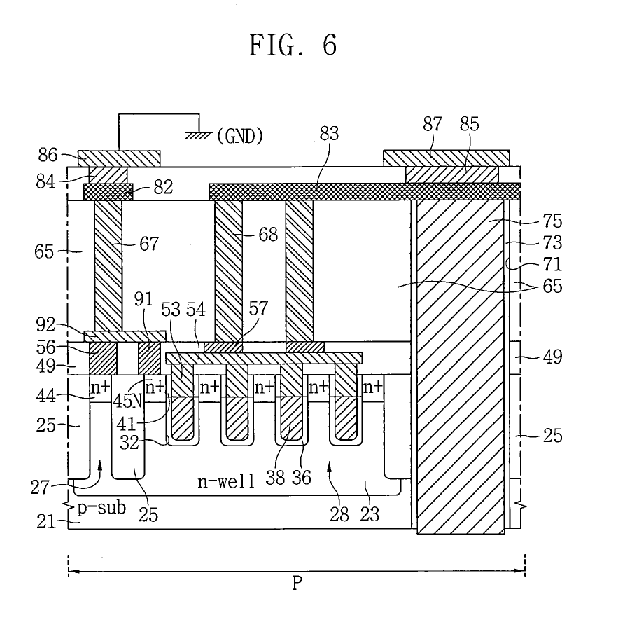

Referring to FIG. 6, a first impurity area 44 and second impurity areas 45N may include n-type impurities. The second impurity areas 45N may be formed adjacent to both sides of capping patterns 41. A ninth plug 91 passing through a first insulating layer 49 and in contact with the second impurity areas 45N may be formed. The ninth plug 91 may include a conductive layer, such as Ti, TiN, Ta, TaN, W, WN, Ni, Co, Al, Pt, Ag, conductive carbon, or a combination thereof. A fifth interconnection 92 in contact with a second plug 56 and the ninth plug 91 may be formed on the first insulating layer 49. The fifth interconnection 92 may include a conductive layer, such as Ti, TiN, Ta, TaN, W, WN, Ni, Co, Al, Pt, Ag, conductive carbon, or a combination thereof. A fifth plug 67 may be in contact with the fifth interconnection 92 through a second insulating layer 65.

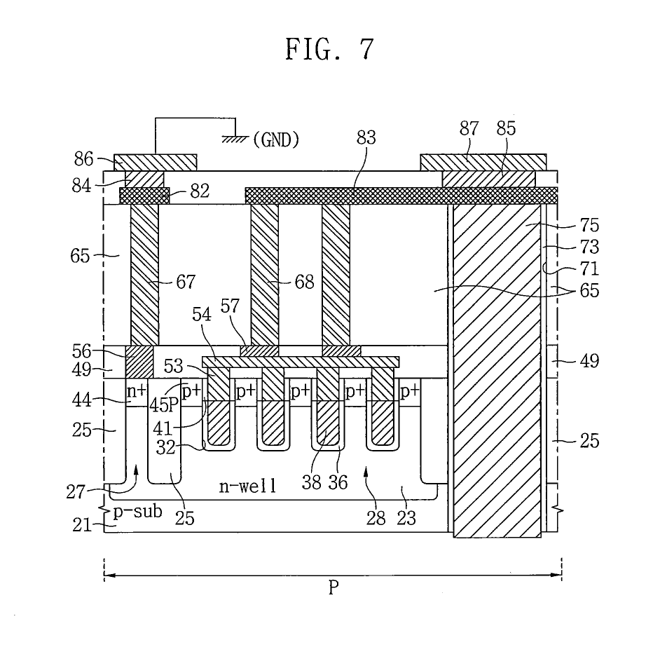

Referring to FIG. 7, a first impurity area 44 may include n-type impurities, and second impurity areas 45P may include p-type impurities.

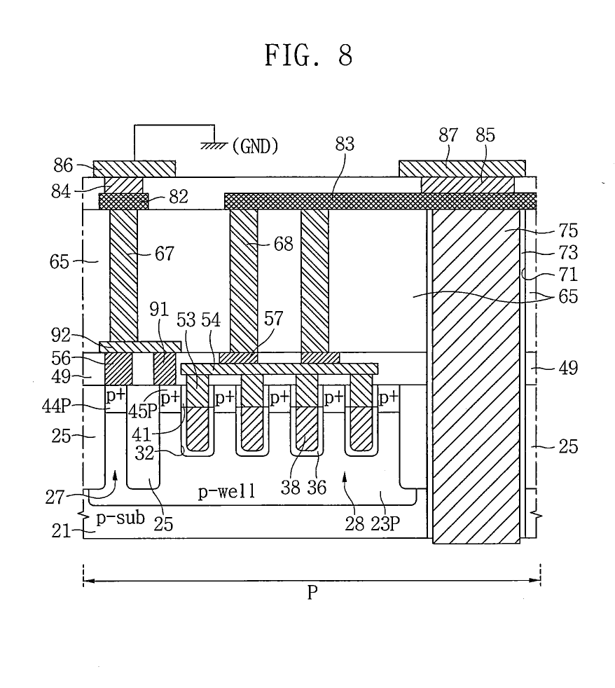

Referring to FIG. 8, a second well 23P may include p-type impurities. A first impurity area 44P and second impurity areas 45P may include p-type impurities. A second active region 27 and a third active region 28 may include p-type impurities. The p-type impurities may be boron (B).

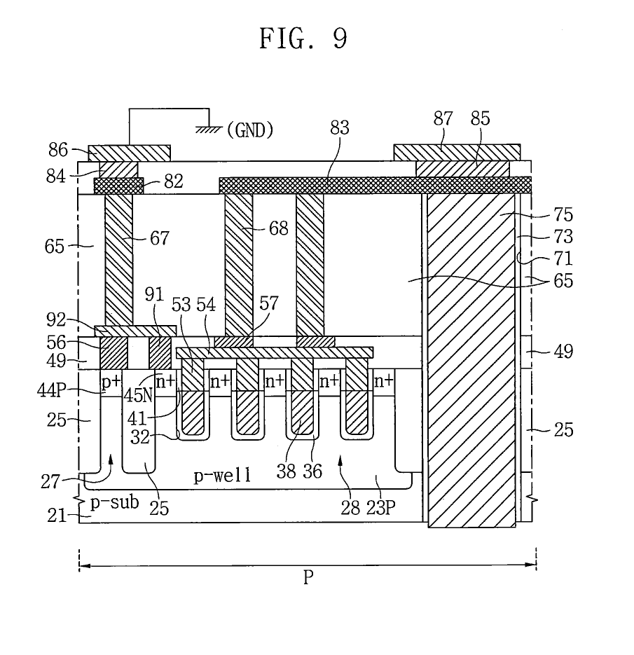

Referring to FIG. 9, a second well 23P may include p-type impurities. A second active region 27 and a third active region 28 may include p-type impurities. A first impurity area 44P may include p-type impurities, and second impurity areas 45N may include n-type impurities.

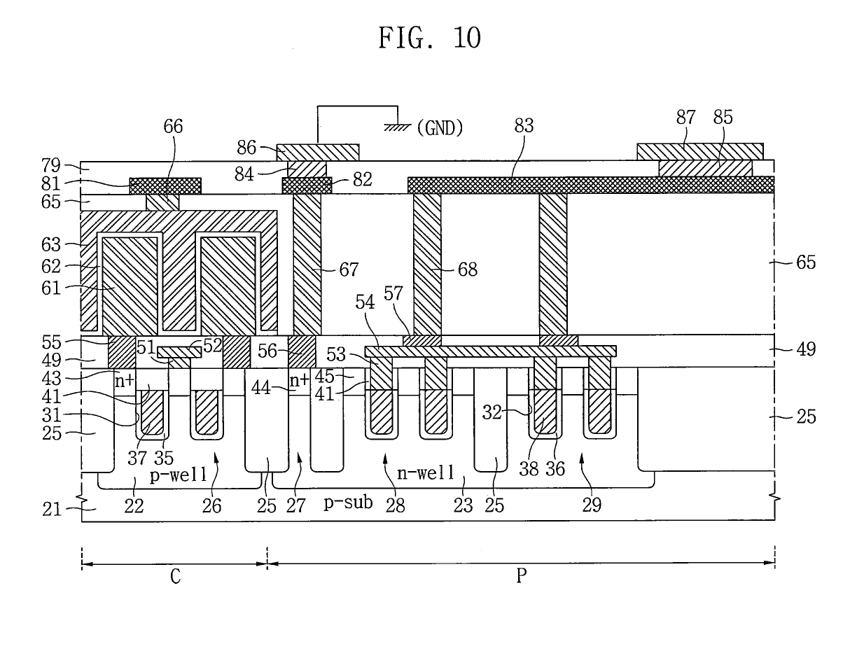

Referring to FIG. 10, the through-electrode (reference numeral 75 in FIG. 1) may be omitted.

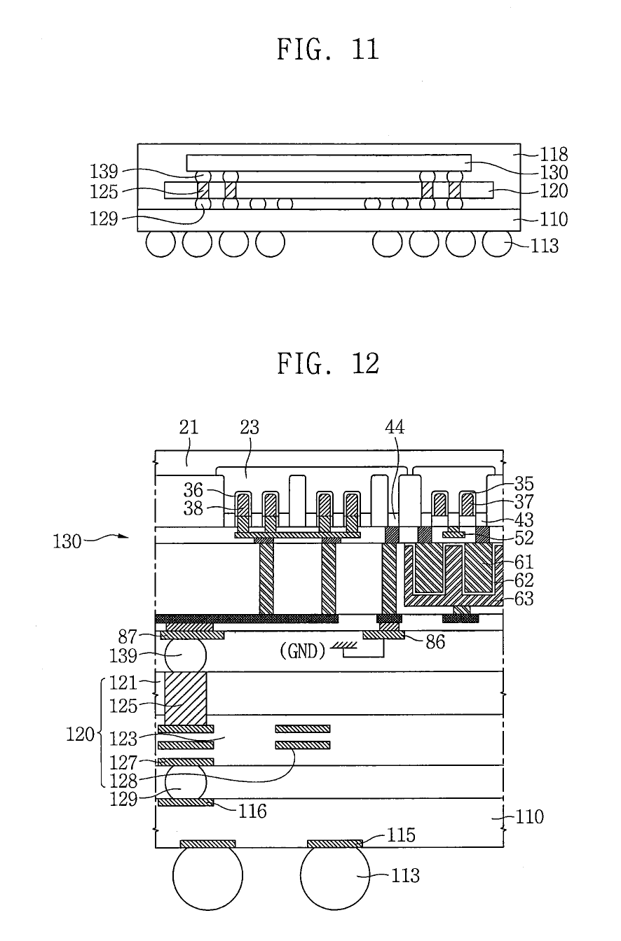

FIG. 11 is a cross-sectional view for describing a semiconductor device in accordance with embodiments of the inventive concept, and FIG. 12 is an enlarged view showing a part of FIG. 11 in detail. The semiconductor device in accordance with the embodiments of the inventive concept may be a multi-chip package.

Referring to FIGS. 11 and 12, a first semiconductor chip 120 may be mounted on a package substrate 110. A second semiconductor chip 130 may be mounted on the first semiconductor chip 120. An encapsulant 118 covering the first semiconductor chip 120 and the second semiconductor chip 130 may be formed on the package substrate 110. An external terminal 113 may be formed on a bottom of the package substrate 110. A first connection terminal 129 may be formed between the package substrate 110 and the first semiconductor chip 120. The first semiconductor chip 120 may include a through-electrode 125. A second connection terminal 139 may be formed between the first semiconductor chip 120 and the second semiconductor chip 130.

The package substrate 110 may include a rigid printed circuit board, a flexible printed circuit board, or a rigid-flexible printed circuit board. The package substrate 110 may include an external pad 115 and a finger electrode 116. The external pad 115 may be electrically connected to the finger electrode 116. The external terminal 113 may be formed on the external pad 115. The external terminal 113 may be exposed on the bottom of the package substrate 110. The external pad 115 and the finger electrode 116 may include a conductive layer, such as Cu, W, WN, Al, AlN, Ti, TiN, Ta, TaN, Ni, Ag, Au, Pt, Sn, or a combination thereof. The external terminal 113 may include a solder ball, a conductive bump, a pin grid array (PGA), a lead grid array (LGA), or a combination thereof. The external terminal 113 may be omitted. The external pad 115 may be exposed on the bottom of the package substrate 110. Both of the external terminal 113 and the external pad 115 may be omitted. The encapsulant 118 may include a molding compound.

The first semiconductor chip 120 may be a logic chip. The first semiconductor chip 120 may include a semiconductor substrate 121, the through-electrode 125, an interlayer insulating layer 123, a lower pad 127, and a plurality of internal circuits 128. The interlayer insulating layer 123, the lower pad 127, and the plurality of internal circuits 128 may configure an active surface of the first semiconductor chip 120. The active surface 123, 127, and 128 may be disposed under the semiconductor substrate 121. The through-electrode 125 may be electrically connected to the lower pad 127 through the semiconductor substrate 121. The through-electrode 125 may be electrically connected to the plurality of internal circuits 128.

The through-electrode 125 may include a conductive layer, such as Cu, W, WN, Al, AlN, Ti, TiN, Ta, TaN, Ni, Ag, Au, Pt, Sn, or a combination thereof. The through-electrode 125 may be isolated from the semiconductor substrate 121. The through-electrode 125 may function to transfer a data signal of the first semiconductor chip 120 and/or the second semiconductor chip 130. The interlayer insulating layer 123 may include an insulating layer, such as silicon oxide, silicon nitride, silicon oxynitride, or a combination thereof. The lower pad 127 may be formed on the interlayer insulating layer 123. The lower pad 127 may include a conductive layer, such as Cu, W, WN, Al, AlN, Ti, TiN, Ta, TaN, Ni, Ag, Au, Pt, Sn, or a combination thereof. The plurality of internal circuits 128 may be formed inside of the interlayer insulating layer 123 and/or between the interlayer insulating layer 123 and the semiconductor substrate 121. The plurality of internal circuits 128 may include active/passive devices, such as a transistor, a resistor, a capacitor, an inductor, and an electrical interconnection.

The first connection terminal 129 may be formed between the finger electrode 116 of the package substrate 110, and the lower pad 127 of the first semiconductor chip 120. The first connection terminal 129 may include a solder ball, a conductive bump, a conductive spacer, or a combination thereof.

The second semiconductor chip 130 may be a memory chip. The second semiconductor chip 130 may include a semiconductor device having a similar configuration to that described with reference to FIGS. 1 to 10. For example, the second semiconductor chip 130 may be a DRAM chip having a similar configuration to that described with reference to FIG. 10. The second semiconductor chip 130 may include the gate dielectric layer 35, the gate electrode 37, the source/drain areas 43, the second well 23, the capacitor dielectric layer 36, the upper electrode 38, the first impurity area 44, the bit line 52, the cell lower electrode 61, the cell capacitor dielectric layer 62, the cell upper electrode 63, the first pad 86, and the second pad 87. The cell lower electrode 61, the cell capacitor dielectric layer 62, and the cell upper electrode 63 may configure a cell capacitor. The second well 23 may be connected to a ground GND. The second well 23 may function as a lower electrode. The upper electrode 38, the capacitor dielectric layer 36, and the second well 23 may configure a decoupling capacitor.

The second connection terminal 139 may be formed between the second pad 87 of the second semiconductor chip 13, and the through-electrode 125 of the first semiconductor chip 120. The second connection terminal 139 may include a solder ball, a conductive bump, a conductive spacer, or a combination thereof.

The second pad 87 of the second semiconductor chip 130 may be electrically connected to the bit line 52, the gate electrode 37, or the cell upper electrode 63. The first semiconductor chip 120 may be electrically connected to the bit line 52, gate electrode 37, or cell upper electrode 63 of the second semiconductor chip 130 via the through-electrode 125, the second connection terminal 139, and the second pad 87. The decoupling capacitor 23, 36, and 38 may function to reduce/block noise in a data transfer path between the first semiconductor chip 120 and the second semiconductor chip 130.

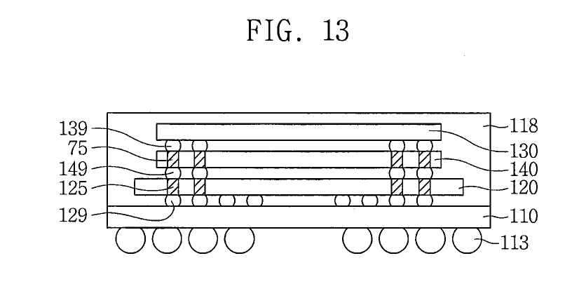

FIG. 13 is a cross-sectional view for describing a semiconductor device in accordance with embodiments of the inventive concept, and FIG. 14 is an enlarged view showing a part of FIG. 13 in detail.

Referring to FIGS. 13 and 14, a first semiconductor chip 120 may be mounted on a package substrate 110. A second semiconductor chip 130 may be mounted on the first semiconductor chip 120. A third semiconductor chip 140 may be mounted between the first semiconductor chip 120 and the second semiconductor chip 130. An encapsulant 118 covering the first semiconductor chip 120, the third semiconductor chip 140, and the second semiconductor chip 130 may be formed on the package substrate 110. A first connection terminal 129 may be formed between the package substrate 110 and the first semiconductor chip 120. The first semiconductor chip 120 may include a through-electrode 125. A third connection terminal 149 may be formed between the first semiconductor chip 120 and the third semiconductor chip 140. A second connection terminal 139 may be formed between the third semiconductor chip 140 and the second semiconductor chip 130.

The third semiconductor chip 140 may be a memory chip. The third semiconductor chip 140 may include a semiconductor device having a similar configuration to that described with reference to FIGS. 1 to 10. For example, the third semiconductor chip 140 may be a DRAM chip having a similar configuration to that described with reference to FIG. 1. The third semiconductor chip 140 may include the gate dielectric layer 35, the gate electrode 37, the source/drain areas 43, the second well 23, the capacitor dielectric layer 36, the upper electrode 38, the first impurity area 44, the bit line 52, the cell lower electrode 61, the cell capacitor dielectric layer 62, the cell upper electrode 63, the through-electrode 75, the first pad 86, and the second pad 87. The cell lower electrode 61, the cell capacitor dielectric layer 62, and the cell upper electrode 63 may configure a cell capacitor. The second well 23 may be connected to a ground GND. The second well 23 may function as a lower electrode. The upper electrode 38, the capacitor dielectric layer 36, and the second well 23 may configure a decoupling capacitor.

The third connection terminal 149 may be formed between the second pad 87 of the third semiconductor chip 140, and the through-electrode 125 of the first semiconductor chip 120. The third connection terminal 149 may include a solder ball, a conductive bump, a conductive spacer, or a combination thereof. The second connection terminal 139 may be formed between the second pad 87 of the second semiconductor chip 130, and the through-electrode 75 of the third semiconductor chip 140.

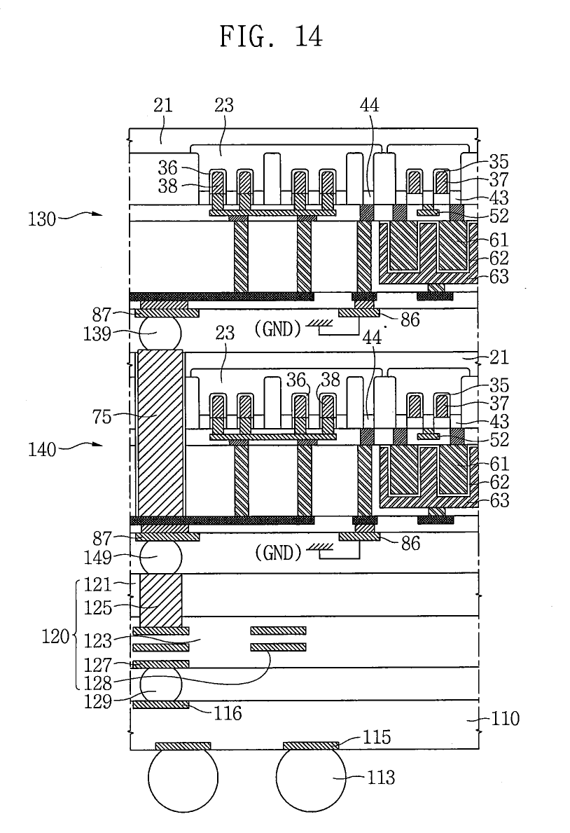

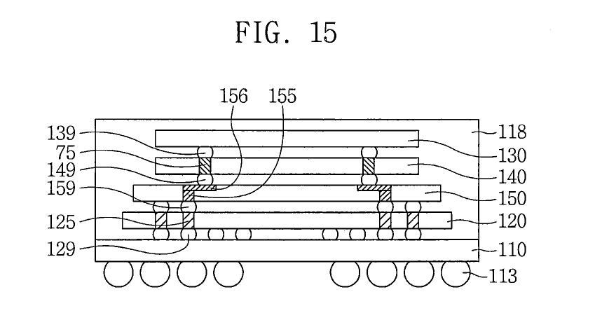

FIG. 15 is a cross-sectional view for describing a semiconductor device in accordance with embodiments of the inventive concept, and FIG. 16 is an enlarged view showing a part of FIG. 15 in detail.

Referring to FIGS. 15 and 16, a first semiconductor chip 120 may be installed on a package substrate 110. An interposer 150 may be mounted on the first semiconductor chip 120. A third semiconductor chip 140 may be mounted on the interposer 150. A second semiconductor chip 130 may be mounted on the third semiconductor chip 140. An encapsulant 118 covering the first semiconductor chip 120, the interposer 150, the third semiconductor chip 140, and the second semiconductor chip 130 may be formed on the package substrate 110. A first connection terminal 129 may be formed between the package substrate 110 and the first semiconductor chip 120. The first semiconductor chip 120 may include a through-electrode 125. A fourth connection terminal 159 may be formed between the first semiconductor chip 120 and the interposer 150. The interposer 150 may include a through-electrode 155 and a finger electrode 156. A third connection terminal 149 may be formed between the interposer 150 and the third semiconductor chip 140. A second connection terminal 139 may be formed between the third semiconductor chip 140 and the second semiconductor chip 130.

The interposer 150 may be a three-dimensional (3D) interposer. The finger electrode 156 may be exposed on a surface of the interposer 150. The through-electrode 155 may be in contact with the finger electrode 156. The interposer 150 may include a semiconductor substrate, a ceramic substrate, a metal substrate, a plastic substrate, a glass substrate, or a combination thereof. The through-electrode 155 and the finger electrode 156 may include a conductive layer, such as Cu, W, WN, Al, AlN, Ti, TiN, Ta, TaN, Ni, Ag, Au, Pt, Sn, or a combination thereof.

The fourth connection terminal 159 may be formed between the through-electrode 155 of the interposer 150, and the through-electrode 125 of the first semiconductor chip 120. The fourth connection terminal 159 may include a solder ball, a conductive bump, a conductive spacer, or a combination thereof. The third connection terminal 149 may be formed between the second pad 87 of the third semiconductor chip 140, and the finger electrode 156 of the interposer 150. The third connection terminal 149 may be offset from the fourth connection terminal 159.

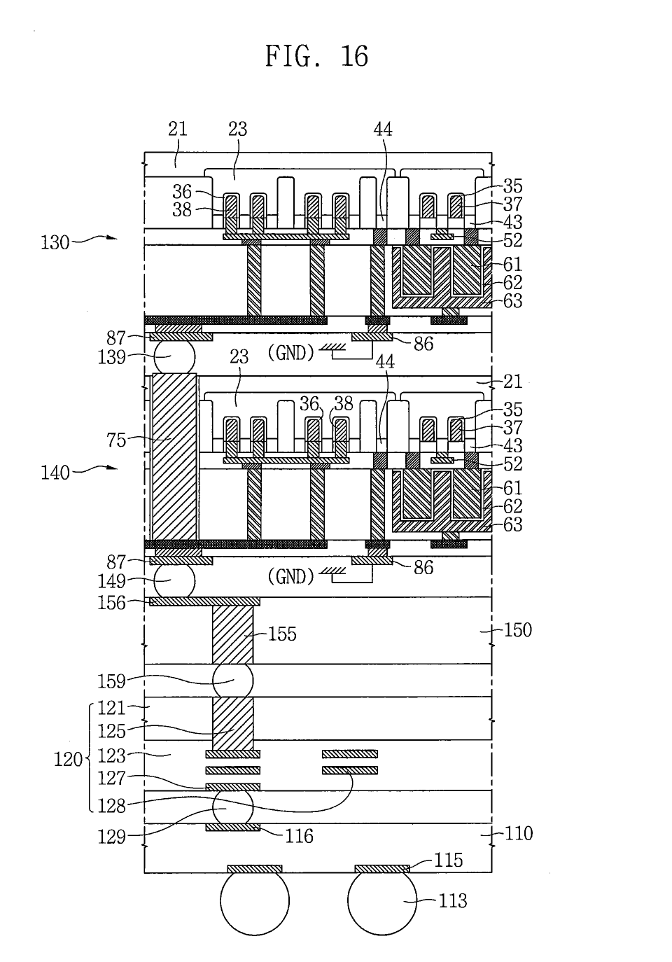

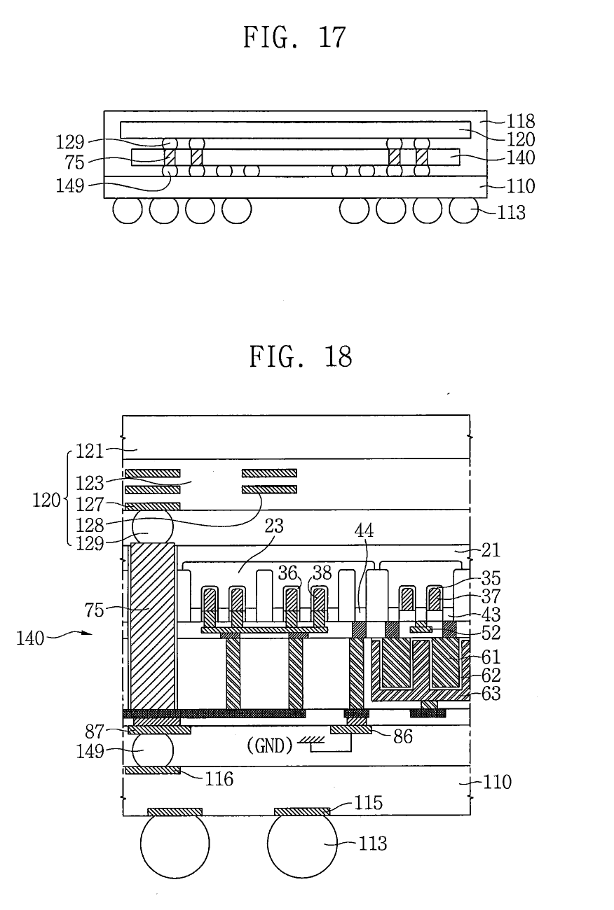

FIG. 17 is a cross-sectional view for describing a semiconductor device in accordance with embodiments of the inventive concept, and FIG. 18 is an enlarged view showing a part of FIG. 17 in detail.

Referring to FIGS. 17 and 18, a third semiconductor chip 140 may be mounted on a package substrate 110. A first semiconductor chip 120 may be mounted on the third semiconductor chip 140. An encapsulant 118 covering the third semiconductor chip 140 and the first semiconductor chip 120 may be formed on the package substrate 110. A third connection terminal 149 may be formed between the package substrate 110 and the third semiconductor chip 140. The third semiconductor chip 140 may include a through-electrode 75. A first connection terminal 129 may be formed between the third semiconductor chip 140 and the first semiconductor chip 120.

The third semiconductor chip 140 may be a memory chip. The third semiconductor chip 140 may include a semiconductor device having a similar configuration to that described with reference to FIGS. 1 to 10. For example, the third semiconductor chip 140 may be a DRAM chip having a similar configuration to that described with reference to FIG. 1.

The first semiconductor chip 120 may be a logic chip. The first semiconductor chip 120 may include a semiconductor substrate 121, an interlayer insulating layer 123, a lower pad 127, and a plurality of internal circuits 128. The interlayer insulating layer 123, the lower pad 127, and the plurality of internal circuits 128 may configure an active surface of the first semiconductor chip 120. The active surfaces 123, 127, and 128 may be disposed under the semiconductor substrate 121. The lower pad 127 may be electrically connected to the plurality of internal circuits 128.

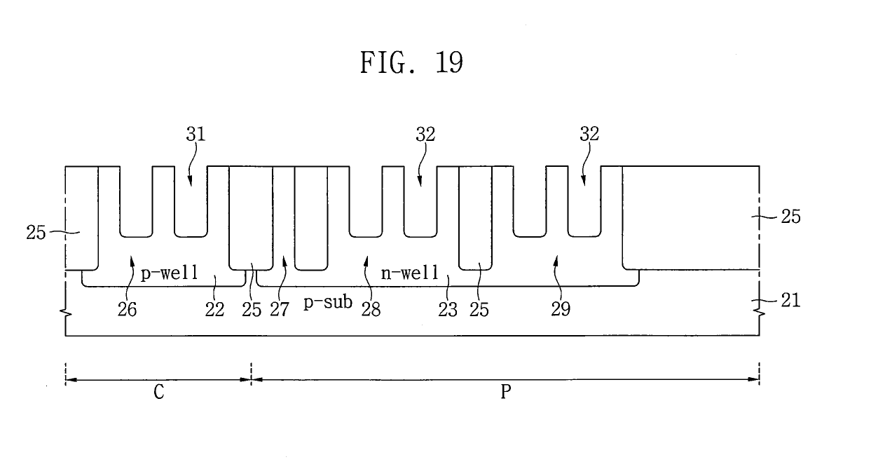

FIGS. 19 to 26 are cross-sectional views for describing a method of forming a semiconductor device in accordance with embodiments of the inventive concept.

Referring to FIG. 19, a first well 22 and a second well 23 may be formed in a predetermined region of a semiconductor substrate 21 including a cell region C and a peripheral circuit region P. A device isolation layer 25 defining a first active region 26, a second active region 27, a third active region 28, and a fourth active region 29 may be formed on the semiconductor substrate 21. A gate trench 31 may be formed in the first active region 26. A capacitor trench 32 may be formed in the third active region 28 and the fourth active region 29.

The semiconductor substrate 21 may be a silicon wafer, or a silicon on insulator (SOI) wafer. For example, the semiconductor substrate 21 may be a single crystalline silicon wafer including p-type impurities. The first well 22 and the second well 23 may be spaced apart from each other. The first well 22 may be confined in the cell region C. The second well 23 may be confined in the peripheral circuit region P. The first well 22 may include p-type impurities. The second well 23 may include n-type impurities.

The device isolation layer 25 may be formed using a shallow trench isolation (STI) technique. The device isolation layer 25 may include an insulating layer, such as silicon oxide, silicon nitride, silicon oxynitride, or a combination thereof. The first active region 26 may be confined in the first well 22. The second active region 27, the third active region 28, and the fourth active region 29 may be confined in the second well 23. Each of the third active region 28 and the fourth active region 29 may have substantially the same size and shape as the first active region 26. Each of the third active region 28 and the fourth active region 29 may have substantially the same horizontal width as the first active region 26.

The gate trenches 31 may be formed in parallel. For example, a pair of gate trenches 31 crossing the first active region 26 may be formed. The first active region 26 may be exposed on a sidewall and a bottom of the gate trench 31. Single crystalline silicon including p-type impurities may be exposed on the sidewall and bottom of the gate trench 31. The capacitor trenches 32 may be formed in parallel. For example, a pair of capacitor trenches 32 crossing the third active region 28, and another pair of capacitor trenches 32 crossing the fourth active region 29 may be formed. The third active region 28 or the fourth active region 29 may be exposed on a sidewall and a bottom of the capacitor trench 32. Single crystalline silicon including n-type impurities may be exposed on the sidewall and bottom of the capacitor trench 32.

The process of forming the capacitor trench 32, and the process of forming the gate trench 31 may include an isotropic etching process simultaneously performed in a single chamber under the same process conditions. The capacitor trench 32 may have substantially the same size and shape as the gate trench 31. The capacitor trench 32 may have substantially the same horizontal width and vertical depth as the gate trench 31. The bottom of the capacitor trench 32 may be formed substantially at the same level as the bottom of the gate trench 31.

In other embodiments, the capacitor trench 32 may have various shapes. The capacitor trench 32 may have an upper width smaller or greater than a lower width. The capacitor trench 32 may have a spherical-shaped lower end having greater width than an upper end.

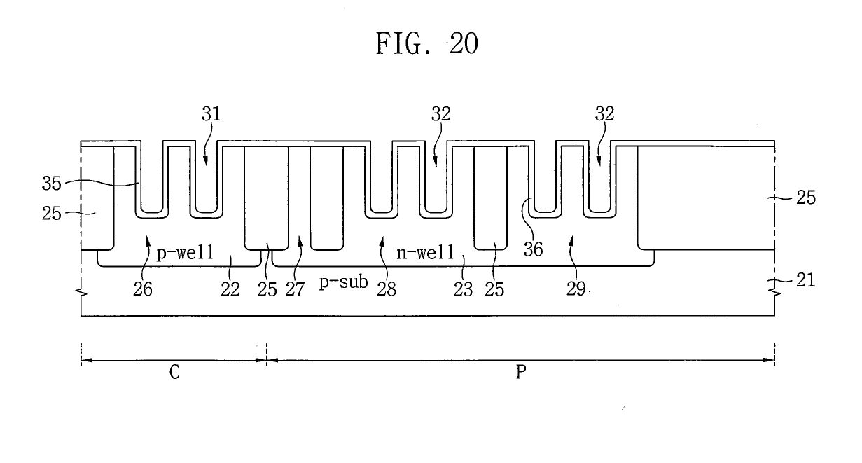

Referring to FIG. 20, a gate dielectric layer 35 covering the sidewall and bottom of the gate trench 31 may be formed. A capacitor dielectric layer 36 covering the sidewall and bottom of the capacitor trench 32 may be formed.

A process of forming the gate dielectric layer 35 and a process of forming the capacitor dielectric layer 36 may include a thin film formation process simultaneously performed in a single chamber under the same process condition. The gate dielectric layer 35 and the capacitor dielectric layer 36 may have substantially the same thickness. The gate dielectric layer 35 and the capacitor dielectric layer 36 may include the same material layer. The gate dielectric layer 35 and the capacitor dielectric layer 36 may include a dielectric layer, such as silicon oxide, silicon nitride, silicon oxynitride, high-K dielectrics, or a combination thereof.

In other embodiments, the capacitor dielectric layer 36 may include a different material from the gate dielectric layer 35.

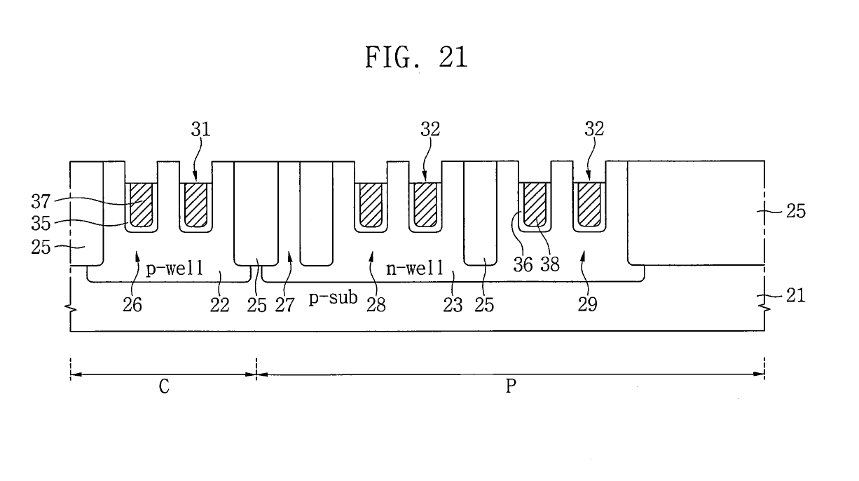

Referring to FIG. 21, a gate electrode 37 may be formed in the gate trench 31. An upper electrode 38 may be formed in the capacitor trench 32. The upper electrode 38, the capacitor dielectric layer 36, and the second well 23 may configure a decoupling capacitor. The second well 23 may be connected to a ground GND. The second well 23 may function as a lower electrode.

A process of forming the gate electrode 37 and a process of forming the upper electrode 38 may include a thin film formation process simultaneously performed in a single chamber under the same process condition. The gate electrode 37 and the upper electrode 38 may include the same material layer. The gate electrode 37 and the upper electrode 38 may include a conductive layer, such as Ti, TiN, Ta, TaN, W, WN, Ni, Co, Al, Pt, Ag, conductive carbon, or a combination thereof. The upper electrode 38 may have substantially the same size and shape as the gate electrode 37. The upper electrode 38 may have substantially the same horizontal width as the gate electrode 37.

Upper ends of the upper electrode 38 and the gate electrode 37 may be formed at a lower level than upper ends of the capacitor trench 32 and the gate trench 31. The upper ends of the upper electrode 38 and the gate electrode 37 may be formed at a lower level than upper ends of the first active region 26, the third active region 28, and the fourth active region 29. The gate dielectric layer 35 may be retained between the first active region 26 and the gate electrode 37, and the capacitor dielectric layer 36 may be retained between the third active region 28 and the upper electrode 38, and between the fourth active region 29 and the upper electrode 38. The upper end of the upper electrode 38 may be formed substantially at the same level as the upper end of the gate electrode 37. A lower end of the upper electrode 38 may be formed substantially at the same level as a lower end of the gate electrode 37.

The gate electrode 37 may be referred to as a buried gate electrode. The gate electrode 37 may be elongated to configure a buried word line.

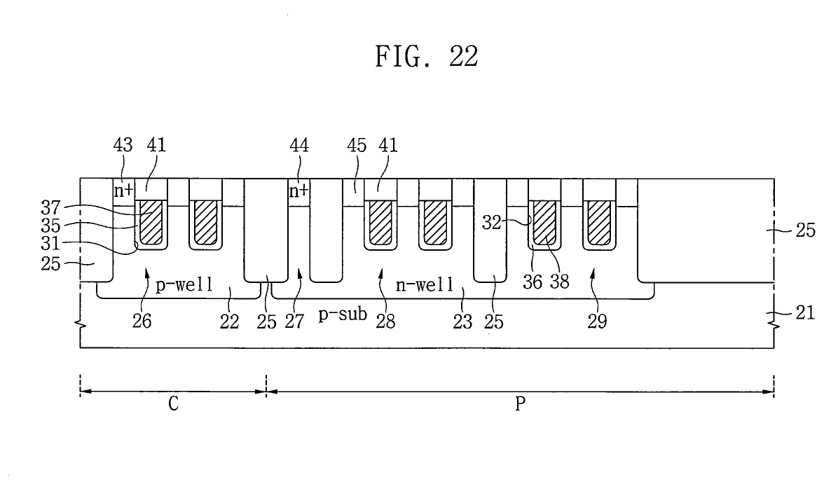

Referring to FIG. 22, capping patterns 41 may be formed on the gate electrode 37 and the upper electrode 38. Source/drain areas 43 may be formed on the first active region 26. A first impurity area 44 may be formed on the second active region 27. Second impurity areas 45 may be formed on the third active region 28 and the fourth active region 29.

The capping patterns 41 may fully fill the gate trench 31 and the capacitor trench 32. The capping patterns 41 may include an insulating layer, such as silicon oxide, silicon nitride, silicon oxynitride, or a combination thereof. The source/drain areas 43, the first impurity area 44, and the second impurity areas 45 may include the same conductivity-type impurities simultaneously formed in the same ion-implantation process. For example, the source/drain areas 43, the first impurity area 44, and the second impurity areas 45 may include n-type impurities. The source/drain areas 43, the first impurity area 44, and the second impurity areas 45 may include phosphorus (P) or arsenic (As).

The source/drain areas 43 may be formed in the first active region 26 adjacent to both ends of the capping patterns 41 using an ion-implantation process. The first active region 26 may be retained under the source/drain areas 43. Lower ends of the source/drain areas 43 may be formed at a lower level than the upper end of the gate electrode 37. The first impurity area 44 may be formed in the second active region 27 using an ion-implantation process. The second active region 27 may be retained under the first impurity area 44. The first impurity area 44 may have a higher impurity concentration than the second active region 27. The second impurity areas 45 may be formed in the third active region 28 and the fourth active region 29 adjacent to both sides of the capping patterns 41. The third active region 28 and the fourth active region 29 may be retained under the second impurity areas 45.

In other embodiments, the first impurity area 44 may include different conductivity-type impurities from the source/drain areas 43. The second impurity areas 45 may include different conductivity-type impurities from the first impurity area 44. The second impurity areas 45 may be omitted.

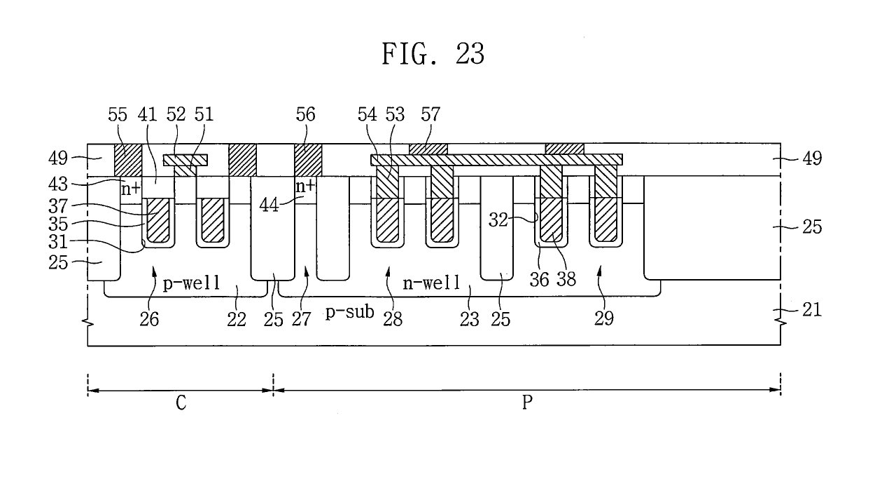

Referring to FIG. 23, a first insulating layer 49 covering the entire semiconductor substrate 21 may be formed. A bit plug 51 and a bit line 52 may be formed in the first insulating layer 49. First plugs 53 passing through the first insulating layer 49 and the capping patterns 41 and in contact with the upper electrode 38 may be formed. A first interconnection 54 in contact with the first plugs 53 may be formed in the first insulating layer 49. A buried contact plug 55 passing through the first insulating layer 49 and in contact with one selected from the source/drain areas 43 may be formed. A second plug 56 passing through the first insulating layer 49 and in contact with the first impurity area 44 may be formed. A third plug 57 passing through the first insulating layer 49 and in contact with the first interconnection 54 may be formed.

The first insulating layer 49 may include silicon oxide, silicon nitride, silicon oxynitride, or a combination thereof. The bit plug 51 may be in contact with the source/drain areas 43 through the first insulating layer 49. The bit line 52 may be in contact with the bit plug 51. Each of the bit plug 51, the bit line 52, the first plugs 53, and the first interconnection 54 may include a conductive layer, such as Ti, TiN, Ta, TaN, W, WN, Ni, Co, Al, Pt, Ag, conductive carbon, or a combination thereof. Each of the buried contact plug 55, the second plug 56, and the third plug 57 may include a conductive layer, such as Ti, TiN, Ta, TaN, W, WN, Ni, Co, Al, Pt, Ag, conductive carbon, or a combination thereof.

The first interconnection 54 may be formed at the same level as the bit line 52. The first interconnection 54 may include the same material layer formed at the same time as the bit line 52.

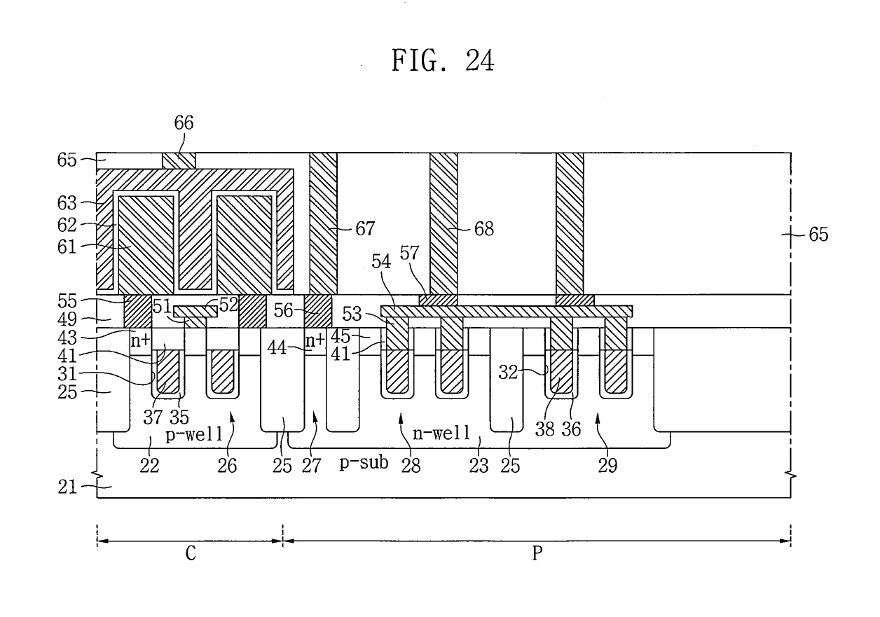

Referring to FIG. 24, a cell lower electrode 61 connected to the buried contact plug 55 may be formed on the first insulating layer 49. A cell capacitor dielectric layer 62 may be formed on the cell lower electrode 61. A cell upper electrode 63 may be formed on the cell capacitor dielectric layer 62. The cell lower electrode 61, the cell capacitor dielectric layer 62, and the cell upper electrode 63 may configure a cell capacitor. A second insulating layer 65 covering the cell upper electrode 63 and the first insulating layer 49 may be formed. A fourth plug 66, a fifth plug 67, and a sixth plug 68 passing through the second insulating layer 65 may be formed.

The cell lower electrode 61 may include a conductive layer, such as Ti, TiN, Ta, TaN, W, WN, Ni, Co, Al, Pt, Ag, conductive carbon, or a combination thereof. The cell capacitor dielectric layer 62 may include silicon oxide, silicon nitride, silicon oxynitride, high-K dielectrics, or a combination thereof. The cell upper electrode 63 may include a conductive layer, such as Ti, TiN, Ta, TaN, W, WN, Ni, Co, Al, Pt, Ag, conductive carbon, or a combination thereof. The second insulating layer 65 may include silicon oxide, silicon nitride, silicon oxynitride, low-K dielectrics, or a combination thereof.

The fourth plug 66 may be in contact with the cell upper electrode 63. The fifth plug 67 may be in contact with the second plug 56. The sixth plug 68 may be in contact with the third plug 57. Each of the fourth plug 66, the fifth plug 67, and the sixth plug 68 may include a conductive layer, such as Cu, W, WN, Al, AlN, Ti, TiN, Ta, TaN, Ni, Ag, Au, Pt, Sn, or a combination thereof.

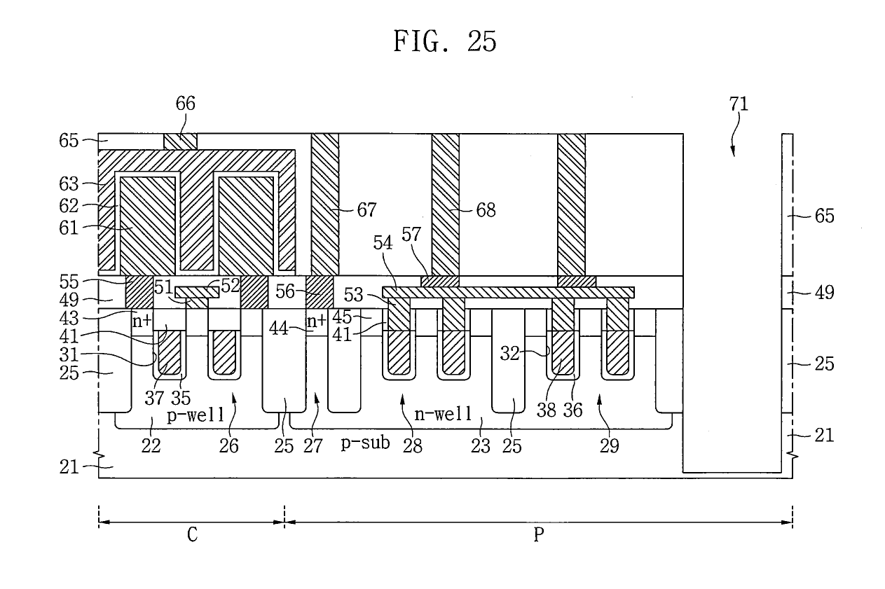

Referring to FIG. 25, a via hole 71 passing through the second insulating layer 65, the first insulating layer 49, and the device isolation layer 25 and penetrating the semiconductor substrate 21 may be formed. The via hole 71 may be formed in the peripheral circuit region P.

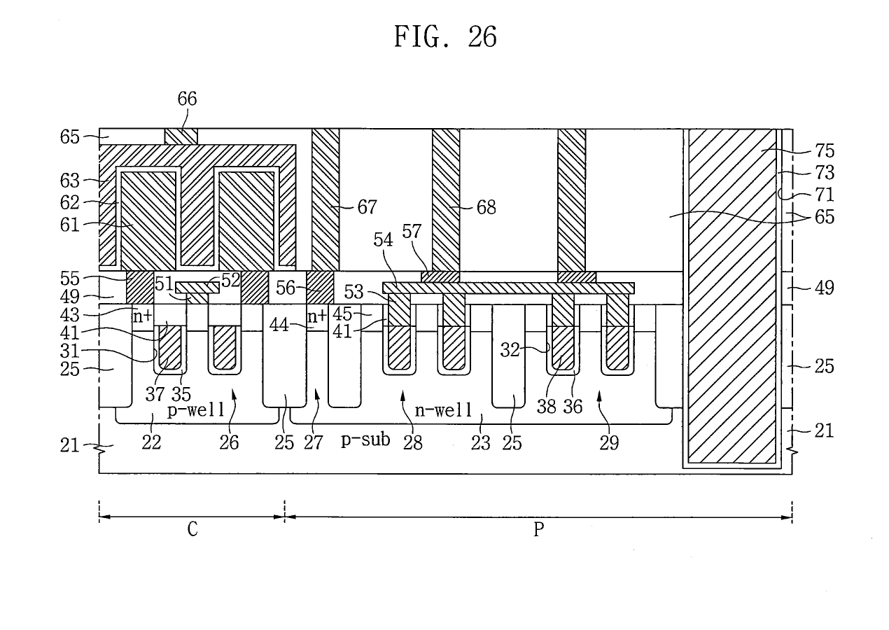

Referring to FIG. 26, a via insulating layer 73 covering a sidewall of the via hole 71 may be formed. A through-electrode 75 filling the via hole 71 may be formed on the via insulating layer 73. The via insulating layer 73 may include silicon oxide, silicon nitride, silicon oxynitride, low-K dielectrics, or a combination thereof. The through-electrode 75 may include a conductive layer, such as Cu, W, WN, Al, AlN, Ti, TiN, Ta, TaN, Ni, Ag, Au, Pt, Sn, or a combination thereof.

Upper surfaces of the through-electrode 75, the second insulating layer 65, the fourth plug 66, the fifth plug 67, and the sixth plug 68 may be exposed substantially on the same plane. A lower end of the through-electrode 75 may be formed at a lower level than lower ends of the gate electrode 37 and the upper electrode 38. A lower ends of the through-electrode 75 may be formed at a lower level than bottoms of the first well 22 and the second well 23. An upper end of the through-electrode 75 may be formed at a higher level than upper ends of the gate electrode 37 and the upper electrode 38.

Referring again to FIG. 1, a third insulating layer 79 may be formed on the second insulating layer 65. A second interconnection 81, a third interconnection 82, a fourth interconnection 83, a seventh plug 84, and an eighth plug 85 may be formed in the third insulating layer 79. A first pad 86 and a second pad 87 may be formed on the third insulating layer 79. The first pad 86 may be in contact with the ground GND. A backside of the semiconductor substrate 21 may be polished to reduce the thickness. An end of the through-electrode 75 may be exposed. The via insulating layer 73 may surround a side surface of the through-electrode 75.

The second interconnection 81 may be in contact with the fourth plug 66. The third interconnection 82 may be in contact with the fifth plug 67. The fourth interconnection 83 may be in contact with the sixth plug 68 and the through-electrode 75. The seventh plug 84 may be in contact with the third interconnection 82. The eighth plug 85 may be in contact with the fourth interconnection 83. The first pad 86 may be in contact with the seventh plug 84. The first pad 86 may be electrically connected to the ground GND. The second pad 87 may be in contact with the eighth plug 85.

The third insulating layer 79 may include silicon oxide, silicon nitride, silicon oxynitride, low-K dielectrics, or a combination thereof. Each of the second interconnection 81, the third interconnection 82, the fourth interconnection 83, the seventh plug 84, the eighth plug 85, the first pad 86, and the second pad 87 may include a conductive layer, such as Cu, W, WN, Al, AlN, Ti, TiN, Ta, TaN, Ni, Ag, Au, Pt, Sn, or a combination thereof.

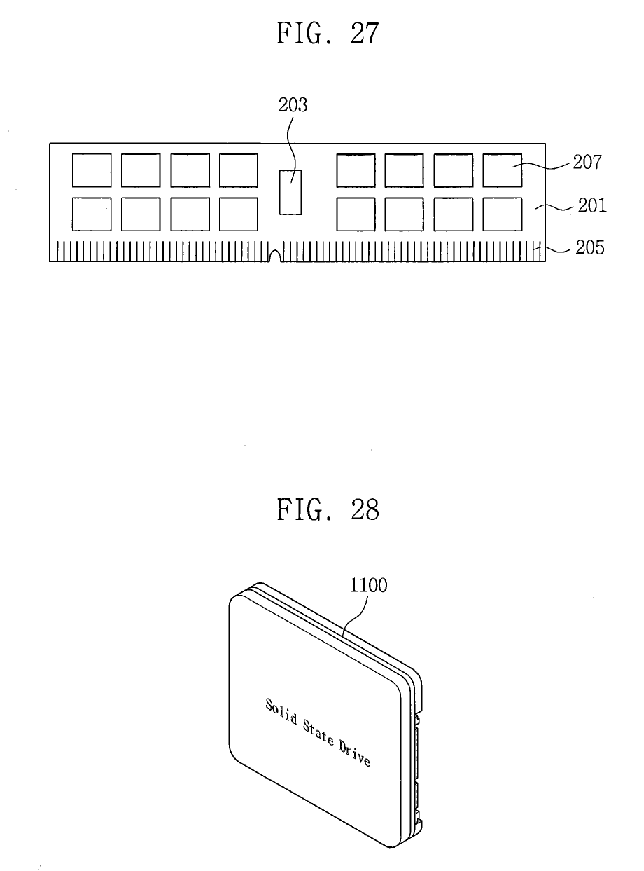

FIG. 27 is a layout for describing a semiconductor module in accordance with embodiments of the inventive concept.

Referring to FIG. 27, the semiconductor module in accordance with the embodiments of the inventive concept may include a module substrate 201, more than one semiconductor package 207, and a control chip package 203. Input/output terminals 205 may be formed on the module substrate 201. At least one of the semiconductor packages 207 and control chip package 203 may include a configuration as described with reference to FIGS. 1 to 26. The semiconductor packages 207 and the control chip package 203 may be installed on the module substrate 201. The semiconductor packages 207 and the control chip package 203 may be electrically connected to the input/output terminals 205 in series/parallel.

The control chip package 203 may be omitted. The semiconductor packages 207 may include a volatile memory chip such as a DRAM and a static random access memory (SRAM), a non-volatile memory chip, such as a flash memory, a phase change memory, a magnetic random access memory (MRAM), or a resistive random access memory (RRAM), or a combination thereof. The semiconductor module in accordance with the embodiments of the inventive concept may be a memory module.

FIG. 28 is a perspective view showing an electronic apparatus in accordance with embodiments of the inventive concept, and FIG. 29 is a system block diagram showing an electronic apparatus in accordance with embodiments of the inventive concept. The electronic apparatus may be a data storage device such as a solid state drive (SSD) 1100.

Referring to FIGS. 28 and 29, the SSD 1100 may include an interface 1113, a controller 1115, a non-volatile memory 1118, and a buffer memory 1119. The SSD 1100 may be an apparatus that stores information using a semiconductor device. The SSD 1100 is faster, has a lower mechanical delay or failure rate, and generates less heat and noise than a hard disk drive (HDD). Further, the SSD 1100 may be smaller and lighter than the HDD. The SSD 1100 may be used in a laptop computer, a netbook, a desktop PC, an MP3 player, or a portable storage device.

The controller 1115 may be formed close to the interface 1113 and electrically connected thereto. The controller 1115 may be a microprocessor including a memory controller and a buffer controller. The non-volatile memory 1118 may be formed close to the controller 1115 and electrically connected thereto. Data storage capacity of the SSD 1100 may correspond to the capacity of the non-volatile memory 1118. The buffer memory 1119 may be formed close to the controller 1115 and electrically connected thereto.

The interface 1113 may be connected to a host 1002, and may transmit and receive electric signals, such as data. For example, the interface 1113 may be a device using a standard such as a Serial Advanced Technology Attachment (SATA), an Integrated Drive Electronics (IDE), a Small Computer System Interface (SCSI), and/or a combination thereof. The non-volatile memory 1118 may be connected to the interface 1113 via the controller 1115. The non-volatile memory 1118 may function to store data received through the interface 1113. Even when power supplied to the SSD 1100 is interrupted, the data stored in the non-volatile memory 1118 may be retained.

The buffer memory 1119 may include a volatile memory. The volatile memory may be a dynamic random access memory (DRAM) and/or a static random access memory (SRAM). The buffer memory 1119 has a relatively faster operating speed than the non-volatile memory 1118.

Data processing speed of the interface 1113 may be relatively faster than the operating speed of the non-volatile memory 1118. Here, the buffer memory 1119 may function to temporarily store data. The data received through the interface 1113 may be temporarily stored in the buffer memory 1119 via the controller 1115, and then permanently stored in the non-volatile memory 1118 according to the data write speed of the non-volatile memory 1118. Further, frequently-used items of the data stored in the non-volatile memory 1118 may be pre-read and temporarily stored in the buffer memory 1119. That is, the buffer memory 1119 may function to increase effective operating speed of the SSD 1100, and reduce error rate.

The controller 1115, the non-volatile memory 1118, and the buffer memory 1119 may have a configuration as described with reference to FIGS. 1 to 26.

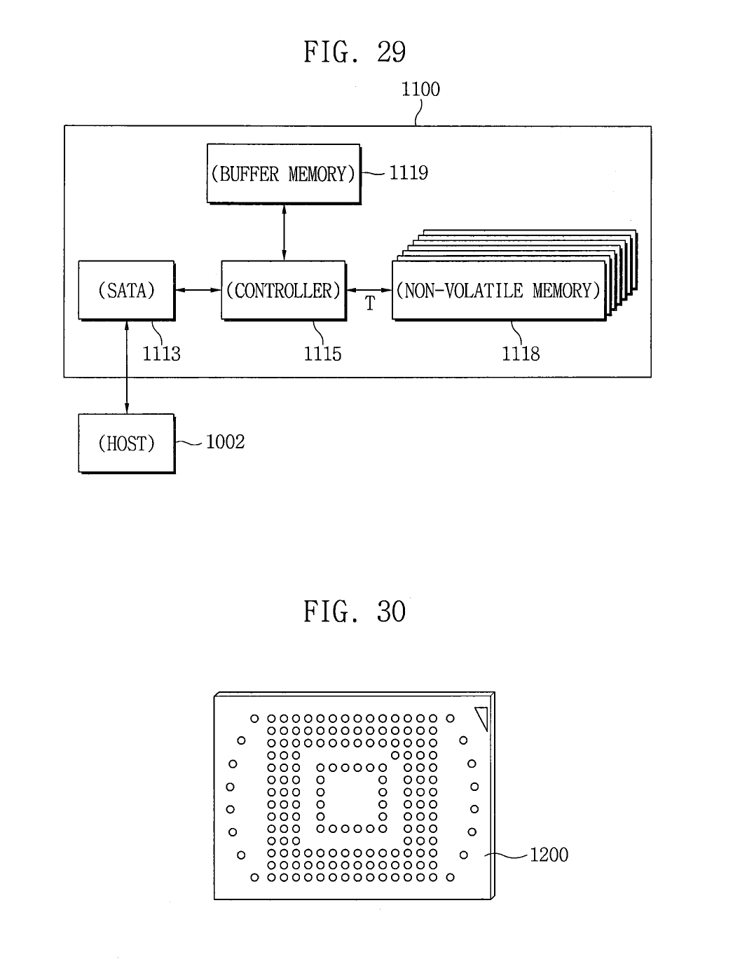

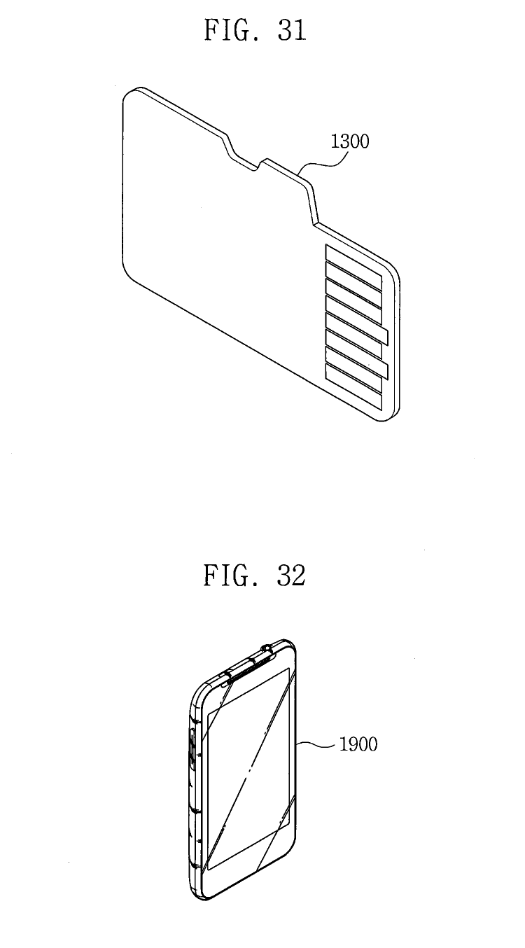

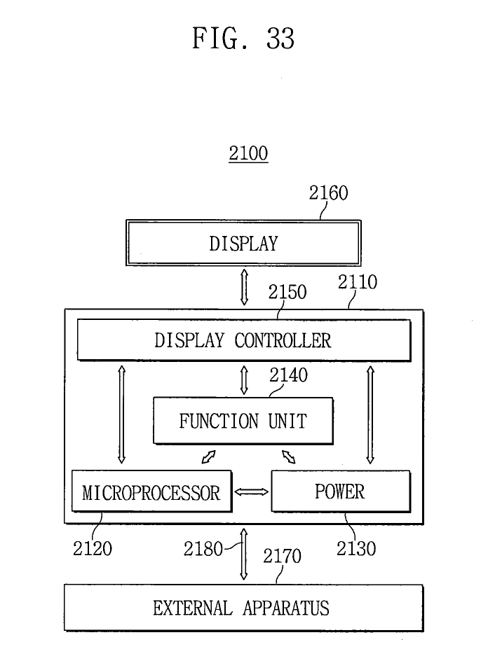

FIGS. 30 to 32 are perspective views showing electronic apparatuses in accordance with embodiments of the inventive concept, and FIG. 33 is a system block diagram of the electronic apparatuses in accordance with embodiments of the inventive concept.

Referring to FIGS. 30 to 32, the semiconductor device described with reference to FIGS. 1 to 26 may be usefully applied to electronic systems, such as an embedded multi-media chip (eMMC) 1200, a micro SD 1300, a smart phone 1900, a netbook, a laptop computer, or a tablet PC. For example, the semiconductor device as described with reference to FIGS. 1 to 26 may be installed in a mainboard of the smart phone 1900. The semiconductor device as described with reference to FIGS. 1 to 26 may be provided to an expansion apparatus, such as the micro SD 1300, to be used combined with the smart phone 1900.

Referring to FIG. 33, the semiconductor device as described with reference to FIGS. 1 to 26 may be applied to an electronic system 2100. The electronic system 2100 may include a body 2110, a microprocessor unit 2120, a power unit 2130, a function unit 2140, and a display controller unit 2150. The body 2110 may be a motherboard formed of a printed circuit board (PCB). The microprocessor unit 2120, the power unit 2130, the function unit 2140, and the display controller unit 2150 may be installed on the body 2110. A display unit 2160 may be arranged inside or outside of the body 2110. For example, the display unit 2160 may be arranged on a surface of the body 2110 and display an image processed by the display controller unit 2150.

The power unit 2130 may receive a constant voltage from an external battery (not shown), etc., divide the voltage into various levels, and supply those voltages to the microprocessor unit 2120, the function unit 2140, and the display controller unit 2150, etc. The microprocessor unit 2120 may receive a voltage from the power unit 2130 to control the function unit 2140 and the display unit 2160. The function unit 2140 may perform various functions of the electronic system 2100. For example, when the electronic system 2100 is a smart phone, the function unit 2140 may have several components which perform functions of the mobile phone such as output of an image to the display unit 2160 or output of a voice to a speaker, by dialing or communication with an external apparatus 2170. If a camera is installed, the function unit 2140 may function as a camera image processor.

In the embodiment to which the inventive concept is applied, when the electronic system 2100 is connected to a memory card, etc. in order to expand capacity, the function unit 2140 may be a memory card controller. The function unit 2140 may exchange signals with the external apparatus 2170 through a wired or wireless communication unit 2180. In addition, when the electronic system 2100 needs a universal serial bus (USB), etc. in order to expand functionality, the function unit 2140 may function as an interface controller. Further, the function unit 2140 may include a mass storage apparatus.

The semiconductor device as described with reference to FIGS. 1 to 26 may be applied to the function unit 2140 or the microprocessor unit 2120.

According to the embodiments of the inventive concept, a decoupling capacitor including a well, a capacitor dielectric layer, and an upper electrode, may be provided in a peripheral region of a semiconductor substrate. The capacitor dielectric layer and the upper electrode may be disposed in a capacitor trench formed in the well. A gate trench, a gate dielectric layer, and a gate electrode may be formed in a cell region of the semiconductor substrate. A through-electrode electrically connected to the upper electrode may be disposed. The capacitor trench may have the same shape as the gate trench. The upper electrode may have the same shape as the gate electrode. Upper ends of the gate electrode and the upper electrode may be formed at a lower level than an upper end of the semiconductor substrate. The decoupling capacitor may have large capacitance compared to existing capacitors. A semiconductor device that achieves high integration and has superior electrical characteristics can be implemented.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

1. An integrated circuit device, comprising:
a semiconductor substrate having first and second semiconductor regions therein;
a gate trench in the first semiconductor region and a gate electrode in the gate trench, said gate electrode having an upper surface below a surface of the semiconductor substrate;
a semiconductor well region in the second semiconductor region;
a capacitor trench in the semiconductor well region and an upper capacitor electrode in the capacitor trench; and
an electrical interconnect electrically connected to the upper capacitor electrode at an interface therebetween, said interface having an upper surface below the surface of the semiconductor substrate.

2. The device of claim 1, wherein a lowermost portion of the gate electrode in the gate trench and a lowermost portion of the upper capacitor electrode in the capacitor trench have equivalent cross-sections when viewed in a first direction parallel to the surface of the semiconductor substrate.

3. The device of claim 1, wherein a depth of the gate trench in the semiconductor substrate is equivalent to a depth of the capacitor trench in the semiconductor substrate.

4. The device of claim 1, wherein the gate electrode is separated from a sidewall and bottom of the gate trench by a gate dielectric layer; wherein the upper capacitor electrode is separated from a sidewall and bottom of the capacitor trench by a capacitor dielectric layer; and wherein the gate dielectric layer and capacitor dielectric layer are equivalent materials.

5. The device of claim 4, wherein the upper capacitor electrode and the gate electrode are equivalent materials.

6. The device of claim 1, wherein the semiconductor well region forms a P-N junction with a surrounding portion of the semiconductor substrate.

7. The device of claim 1, wherein the semiconductor well region is electrically connected to a ground signal line (GND).

8. The device of claim 1, wherein the gate electrode is a gate electrode of a DRAM access transistor; wherein the upper capacitor electrode is an upper capacitor electrode of a decoupling capacitor; and wherein the gate electrode is electrically connected to a word line, which extends parallel to the upper capacitor electrode of the decoupling capacitor.

9. The device of claim 8, wherein the upper capacitor electrode of the decoupling capacitor is electrically connected to a patterned interconnection line extending above the surface of the semiconductor substrate; and wherein the first semiconductor region has a bit line thereon at the same height as the patterned interconnection line relative to the surface of the semiconductor substrate.

10. The device of claim 8, further comprising a through-substrate via (TSV) extending through the semiconductor substrate and a through-substrate electrode in the TSV, which is electrically connected to the upper capacitor electrode of the decoupling capacitor via the patterned interconnection line and electrical interconnect.

11. The device of claim 8, further comprising a solder bond electrically connected to the upper capacitor electrode of the decoupling capacitor via the patterned interconnection line and electrical interconnect.

12. The device of claim 8, further comprising a second semiconductor substrate having a second decoupling capacitor therein; and a solder bond electrically connecting an electrode of the second decoupling capacitor to the TSV.

13. The device of claim 12, wherein the integrated circuit device is a vertically integrated multi-chip DRAM device.

14. A semiconductor device, comprising:
a semiconductor substrate including a cell region and a peripheral circuit region;
a gate trench formed in the cell region of the semiconductor substrate;
a gate electrode formed in the gate trench;
a gate dielectric layer formed between the gate electrode and the semiconductor substrate;
a well formed in the peripheral circuit region of the semiconductor substrate;
a capacitor trench formed in the well and having the same shape as the gate trench;
an upper electrode formed in the capacitor trench;
a capacitor dielectric layer formed between the upper electrode and the well; and
a through-electrode electrically connected to the upper electrode,
wherein upper ends of the gate electrode and the upper electrode are formed at a lower level than an upper end of the semiconductor substrate.

15. The semiconductor device of claim 14, wherein a bottom of the capacitor trench is formed at the same level as a bottom of the gate trench.

16. The semiconductor device of claim 14, wherein the upper electrode has the same shape as the gate electrode.

17. The semiconductor device of claim 14, wherein the upper end of the upper electrode is formed at the same level as the upper end of the gate electrode.

18. The semiconductor device of claim 14, wherein a lower end of the upper electrode is formed at the same level as a lower end of the gate electrode.

19. The semiconductor device of claim 14, wherein the capacitor dielectric layer is the same material layer as the gate dielectric layer.

20.-26. (canceled)

27. A semiconductor device, comprising:
a first semiconductor chip formed on a substrate;
a second semiconductor chip formed on the first semiconductor chip; and
an encapsulant formed on the substrate and covering the first and second semiconductor chips,
wherein the second semiconductor chip comprises:
a semiconductor substrate including a cell region and a peripheral circuit region;
a gate trench formed in the cell region of the semiconductor substrate;
a gate electrode formed in the gate trench;
a gate dielectric layer formed between the gate electrode and the semiconductor substrate;
a well formed in the peripheral circuit region of the semiconductor substrate;
a capacitor trench formed in the well and having the same shape as the gate trench;
an upper electrode formed in the capacitor trench;
a capacitor dielectric layer formed between the upper electrode and the well; and
a first through-electrode electrically connected to the upper electrode,
wherein upper ends of the gate electrode and the upper electrode are formed at a lower level than an upper end of the semiconductor substrate.

28.-37. (canceled)
